(19) United States
(12) Patent Application Publication
(10) Pub. No.: US 2026/0293167 A1
(43) Pub. Date: Sep. 24, 2026

(54) SEMICONDUCTOR COMPONENT WITH INTEGRATED GALVANIC ISOLATION AND METHOD FOR PRODUCING SAID SEMICONDUCTOR COMPONENT

(71) Applicant: Fraunhofer-Gesellschaft zur Förderung der angewandten Forschung e.V., München (DE)

(72) Inventor: Michael BASLER, Freiburg (DE)

(73) Assignee: Fraunhofer-Gesellschaft zur Förderung der angewandten Forschung e.V., München (DE)

(21) Appl. No.: 19/570,412

(22) Filed: Mar. 18, 2026

(30) Foreign Application Priority Data
Mar. 20, 2025 (DE) 102025110895.1

(51) Int. Cl. H10D 1/20

(52) U.S. Cl. CPC H10D 1/20

(57) ABSTRACT

A semiconductor component with integrated galvanic isolation and method for producing the semiconductor component with transmission of data and/or power between two galvanically isolated circuit domains. The method includes providing an isolating substrate with top and bottom sides, forming a semiconductor layer structure with epitaxial layers on the top side, with circuits composed of circuit components of at least one of the circuit domains, applying front-side metallization in a front-side metallization plane on the front side of the semiconductor layer structure facing away from the substrate, the front-side metallization having a front-side transmission element for galvanic isolation, applying rear-side metallization in a rear-side metallization plane on the bottom side of the substrate facing away from the semiconductor layer structure, the rear-side metallization plane having a rear-side transmission element for galvanic isolation, and forming an electrically conductive connection between at least one circuit domain and the front-side or rear-side transmission element.

### CROSS-REFERENCE TO RELATED APPLICATIONS

This application claims priority from German Patent Application No. 10 2025 110 895.1, filed Mar. 20, 2025, which is incorporated herein by reference as if fully set forth.

### TECHNICAL FIELD

The invention relates to a method for producing a semiconductor component with transmission of data and/or power between two galvanically isolated circuit domains and to a semiconductor component with transmission of data and/or power between two galvanically isolated circuit domains.

### BACKGROUND

In the case of semiconductor components with galvanic isolation (also known as galvanic decoupling or potential isolation), two electrical circuits are isolated from one another so that there is no direct electrical connection while signals and/or power can still be transmitted. Such semiconductor components with galvanic isolation (hereinafter also referred to as isolation components) are required in applications for increasing safety, reducing interference and meeting regulatory standards. The reasons for this are primarily personal protection, but also the protection of sensitive component parts, the reduction of interference and earth loops, or else functional integrity at different potentials. More and more industrial and medical standards require high-voltage and low-voltage circuits to be isolated from one another to protect users and equipment.

Multiple methods are known for transmitting data and/or power despite electrical isolation:

In the case of data transmission, traditional isolation components are based, for example, on optical transmission, usually in the near-infrared range. The degree of isolation of such an optocoupler is determined by the distance and the dielectric material between the light source and the photodetector.

Alternatively, isolation components for data transmission based on radio frequencies (RF) with capacitive coupling or inductive coupling are known: RF isolators, for example, use wireless transmission between two stacked or side-by-side chips via silicon-integrated near-field antennas.

Capacitive galvanic isolators suitable for data transmission operate on the basis of, for example, silicon-integrated capacitors. While inductive isolation transformers are suitable for data and/or power transmission. LC hybrid approaches are also known, in which a double isolation barrier in the form of an isolation capacitor and an isolation transformer is used. These approaches are particularly suitable for very high isolation voltages and power transmission.

On the one hand, technologies which exhibit a semiconductor layer structure with active and passive circuits on any carrier substrate are known from the prior art. The galvanic isolation is realized by a separate isolation layer. For example, such an architecture is described in document US 9,935,098 B2. Prior-art systems are complex in terms of production and cost-intensive, but are highly integrable. Another disadvantage is that, for example, products such as digital isolators in these technologies, for example, must be manufactured using two chips/semiconductor components. This is caused by conductive substrates.

Alternatively, it is known from the prior art to construct pure isolation components without additional semiconductor layers for further functionalities with an isolating substrate. Approaches according to this prior art require additional active circuits in semiconductor technologies for the realization of a galvanically isolated data and/or power transmission. The resulting increased space requirement is disadvantageous.

Particularly in the field of power electronics, galvanically isolated gate drivers are used, for example, to control “floating” power transistors or to separate the power unit from the control system. These power semiconductors and power transistors are the key components of all power electronics systems. The standard semiconductor material forms silicon (Si), which is increasingly being replaced by materials with a higher band gap, such as gallium nitride (GaN) or silicon carbide (SiC). In particular, lateral GaN-based power transistors (known as high-electron mobility transistors—HEMTs) are increasingly being used in power electronics systems due to better physical properties and key performance indicators compared to Si-based transistors. Another advantage is the lateral structure in comparison to Si-MOSFETs, for example, which enables the monolithic integration of additional peripherals of the power electronics, such as gate drivers, to the power semiconductor on a chip. First products that monolithically integrate the power transistor and gate driver into a GaN technology are already available. However, isolated GaN gate drivers do not exist yet. A common solution is to control the GaN power transistor using a monolithically integrated gate driver or an external S-gate driver and isolate the signal via a digital isolator based on Si-CMOS or BCD technology. In addition, the supply voltage of the gate driver must be galvanically decoupled using an isolated DC/DC converter.

### SUMMARY

Against this background, it is the object of the invention to propose a semiconductor component for transmitting data and/or power between two galvanically isolated circuit domains that is simple to produce and ensures the required isolation classes.

This method is achieved by a method for producing a semiconductor component having one or more of the features disclosed herein. Preferred refinements of the production method according to the invention are found below and in the claims. The object is further achieved by a semiconductor component according to the invention having one or more of the features disclosed herein. Preferred refinements of this semiconductor component are also found below and in the claims. The wording of all of the claims is hereby explicitly incorporated by reference into the description.

The method according to the invention for producing a semiconductor component with transmission of data and/or power between two galvanically isolated circuit domains comprises the following method steps:
A providing an isolating substrate with a top side and a bottom side;
B forming a semiconductor layer structure by growing and/or depositing epitaxial layers on the top side of the substrate. This forms circuits composed of active and/or passive circuit components for at least one of the two galvanically isolated circuit domains.
C applying a front-side metallization in at least one front-side metallization plane indirectly or directly on the front side of the semiconductor layer structure facing away from the substrate. The front-side metallization comprises a front-side transmission element for the galvanic isolation.
D applying a rear-side metallization in at least one rear-side metallization plane indirectly or directly on the bottom side of the substrate facing away from the semiconductor layer structure. The rear-side metallization plane comprises a rear-side transmission element for the galvanic isolation.
E forming an electrically conductive connection between at least one circuit domain from method step B and the front-side or the rear-side transmission element.

The galvanic isolation is realized by the isolating substrate. The data and/or power is transmitted by means of the front-side and rear-side transmission elements which are arranged on two different sides of the substrate.

On the one hand, this results in the advantage that the galvanic isolation is realized via the substrate. It is not necessary to apply thick isolation layers, as is known from the prior art. This reduces costs. On the other hand, there is the advantage that the isolation element can be realized with integrated circuits from the selected technology and that there is no need to use two technologies and semiconductor systems. Overall, therefore, the semiconductor component may be highly compact.

The object according to the invention is likewise achieved by way of a semiconductor component having one or more of the below-noted features.

The semiconductor component has means for transmitting data and/or power between two galvanically isolated circuit domains. The semiconductor component furthermore comprises an isolating substrate and a semiconductor layer structure comprising circuits composed of active and/or passive circuit components for at least one first circuit domain of the two galvanically isolated circuit domains. The isolating substrate has a top side and a bottom side. The top side and bottom side are selected randomly and do not indicate any restriction.

The semiconductor layer structure is arranged on a top side of the substrate. A front-side metallization plane is arranged in turn on the front side of the semiconductor layer structure. The front side of the semiconductor layer structure is the side of the semiconductor layer structure facing away from the substrate. A front-side transmission element for the galvanic isolation is formed in the front-side metallization plane. A rear-side metallization plane is arranged indirectly or directly on a bottom side of the substrate facing away from the semiconductor layer structure. The rear-side metallization plane comprises a rear-side transmission element for the galvanic isolation.

The front-side and the rear-side transmission elements are designed and arranged to interact to transmit data and/or power contactlessly by way of magnetic coupling, electrical coupling or by means of electromagnetic waves between the front-side transmission element and the rear-side transmission element. The first circuit domain is electrically conductively connected to the front-side transmission element or the rear-side transmission element.

The semiconductor component according to the invention is preferably produced by means of the above-described method according to the invention or a preferred embodiment of the method according to the invention. The method according to the invention is preferably designed to form a semiconductor component according to the invention or a preferred embodiment thereof. The semiconductor component according to the invention also exhibits the aforementioned advantages of the method according to the invention.

In one preferred embodiment of the invention, the semiconductor component is in the form of a monolithically integrated semiconductor component. This results in the advantage that the isolation component can be realized with integrated circuits from the selected technology and that there is no need to use two technologies and semiconductor systems. The solution according to the invention therefore offers the possibility to form the galvanic isolation to the gate driver and/or power transistor in a monolithically integrated manner. Overall, therefore, the semiconductor component may be highly compact.

In another embodiment of the invention, in method step B, both galvanically isolated circuit domains are formed in the semiconductor layer structure. A first and a second circuit domain are formed in the semiconductor layer structure. This results in the advantage that the entire semiconductor component can be formed in a simple and cost-effective manner using semiconductor technology. The semiconductor component thus comprises two areas, the two circuit domains, in the semiconductor layer structure with active and/or passive circuit components having certain desired functionalities.

In an additional method step, electrically conductive connections are preferably formed between the two circuit domains and each transmission element for the transmission of data and/or power. Alternatively, an electrically conductive connection may be formed between the first circuit domain and the front-side transmission element and between the second circuit domain and the rear-side transmission element, or an electrically conductive connection may be formed between the first circuit domain and the rear-side transmission element and between the second circuit domain and the front-side transmission element. Depending on the variant, corresponding vias are formed.

Data and/or power is transmitted between the front-side and the rear-side transmission element inductively, capacitively and/or by way of electromagnetic waves by means of an RF antenna arrangement. All three approaches have different advantages and disadvantages, which are well known from the prior art.

The semiconductor component according to the invention preferably comprises means for the inductive and/or capacitive transmission of data and/or power or an RF antenna arrangement for the transmission of data and/or power by electromagnetic waves:

For the inductive transmission of data and/or power, the front-side and the rear-side transmission element are preferably in the form of a pair of coils: Therefore, at least two coils which are arranged on different sides of the isolation barrier for the galvanic isolation are provided. The inductive coupling is preferably realized by means of a microtransformer. The transformer comprises a primary winding and a secondary winding arranged on opposite sides of the isolation barrier. In principle, the data and/or power transmission may be as known from the prior art. The front-side and the rear-side transmission element are preferably formed as spiral coils. In particular, the number of windings of the coils is between 1 and 30, most preferably 3 to 10 windings.

Data and/or power is preferably capacitively transmitted between the front-side and the rear-side transmission element by means of a capacitor. For this purpose, the front-side and the rear-side transmission element for the transmission of data and/or power are in the form of capacitor plates. The two capacitor plates are respectively arranged on opposite sides of the isolation barrier. This embodiment can also be carried out in principle as is known from the prior art.

Combinations such as LC hybrid approaches are also within the scope of the invention. In particular, very high isolations are achieved by LC hybrid approaches, i.e. by combining inductive and capacitive coupling. These isolation components are realized by way of a double isolation barrier in the form of an isolation capacitor and an isolation transformer. Such systems are described, for example, in the publications N. Greco et al., “A 100-mW fully integrated DC-DC converter with double galvanic isolation,” in ESSCIRC 2017-43rd IEEE European Solid State Circuits Conference, Leuven, Belgium, 2017, pp. 291-294. and N. Greco et al. “A Double-Isolated DC-DC Converter Based on Integrated ${LC}$ Resonant Barriers,” IEEE Transactions on Circuits and Systems I: Regular Papers, vol. 65, no. 12, pp. 4423-4433, 2018, doi: 10.1109/TCSI.2018.2840450.

As an alternative, the rear-side and the front-side transmission element for the transmission of data and/or power are in the form of an RF antenna arrangement having a transmitter and a receiver. The semiconductor component is preferably in the form of an RF antenna arrangement for the wireless transmission of data and/or power between integrated near-field antennas.

In one preferred embodiment of the invention, the semiconductor component is formed on the basis of III-V compound semiconductors, in particular preferably in the AlGaN/GaN material system. This results in the advantage that AlGaN/GaN technology can be used to form various active components, such as normally-on and normally-off high-electron mobility transistors (HEMTs), Schottky barrier diodes (SBDs), lateral field-effect rectifiers (LFERs), and passive components, such as resistors, capacitors and inductors, in order to realize the integrated circuits. This makes it easy to draw on previously known process technologies.

The use of lateral GaN transistors (HEMTs) in power electronics is advantageously improved by the invention. With the approach according to the invention, monolithically integrated power transistors with isolated GaN gate drivers are possible using GaN technology.

As an alternative, the semiconductor component is formed on the basis of silicon. Here, too, this results in the advantage that basic, previously known technologies can be drawn on. The semiconductor component can be realized with integrated circuits from the respective technology or from the respective material system, such that it is possible for the galvanic isolation of data and/or power transmission to be highly compact.

In one preferred embodiment of the invention, the isolating substrate is made of sapphire, semi-isolating silicon carbide or is in the form of a silicon-on-isolator substrate. The substrate is preferably in the form of a silicon-on-sapphire substrate. Epitaxial layers can be grown on these substrates using previously known methods. Due to the electrically isolating properties of the substrate materials, the isolation for galvanic isolation can be achieved in a simple and cost-effective manner without the need for additional layers or structures.

In one preferred embodiment of the invention, the thickness of the substrate is selected based on the desired isolation voltage of the semiconductor component in such a way that the galvanic isolation is ensured during operation of the semiconductor component. The isolation voltage is dependent on the thickness of the substrate between the two transmission elements, such that the desired isolation class can be set based on the thickness of the substrate. In this case, a minimum thickness of the wafer substrate is given in order to be able to process the substrate accordingly. The isolation voltage increases as the thickness increases.

This results in the advantage that the isolation voltage can be ensured in a simple manner by way of an existing element, namely the substrate. There is no need to apply additional isolation layers, which usually increase costs.

The required thickness is dependent on the substrate used. Typical examples are: 48 V/μm for sapphire and 300-500 V/μm for semi-isolating SiC. At typical substrate thicknesses of 200 μm for sapphire and 75 μm for semi-isolating SiC, this corresponds to an isolation voltage of approximately 10 kV and >20 kV.

In one preferred embodiment, one or more etching stages are provided in order to increase the coupling between the front-side and the rear-side transmission element. These can be provided, for example, in the substrate. The etching stage is preferably formed in an additional method step as part of the rear-side machining. The etching stages thus increase the efficiency of the coupling.

In one preferred embodiment of the invention, in an additional method step before method step E, at least one etching stage is formed at least in the substrate in an area between the front-side transmission element and the rear-side transmission element by means of an etching method. This method step is preferably carried out as part of the rear-side processing. The etching stages are preferably arranged in the substrate of the semiconductor component. The etching stages increase the coupling between the two transmission elements. This increases the efficiency of the galvanic coupling.

In one preferred embodiment of the invention, at least one first electrical contact area made of metallic material for making contact with the first circuit domain and/or the second circuit domain is formed in the front-side metallization plane. A second electrical contact region made of metallic material is preferably formed for making contact with the rear-side transmission element by means of vias. By means of these vias, the front side of the semiconductor component can therefore also be used to make contact with the rear side.

The front-side metallization plane and/or the rear-side metallization plane are preferably of multi-layer design. Via planes are preferably provided between the metal layers of the front-side metallization plane, which via planes comprise conductive vias. In particular, at least one via plane is preferably provided in the front-side metallization plane, which via plane has at least one conductive via through the substrate to the rear-side metallization plane.

In order to be able to electrically connect the semiconductor component to other circuit parts or the external environment, at least one bonding area is preferably provided, in particular preferably a plurality of bonding areas, which make contact with different structures of the semiconductor component via the electrical metallization planes.

Preferably only these bonding areas, or preferably only one bonding area, are exposed for contact-making purposes. All other structures are preferably covered by a silicon nitride or silicon oxide layer and thus are both electrically isolated and protected. This topmost dielectric layer is preferably in the form of a silicon nitride or silicon oxide layer. This topmost dielectric layer is used simultaneously to passivate the outer side and to make available the bonding areas.

In one preferred embodiment of the method according to the invention, at least the following steps are carried out: First, the front side is processed. For this purpose, a substrate is provided, on which semiconductor layers containing multiple electrical and electronic components or circuits are preferably deposited by means of epitaxy methods. The functionality of these components and circuits is dependent on the later planned application of the semiconductor component.

The active structures are preferably separated or isolated by means of implantation or etching methods.

Multiple metallization planes are applied and connections and conductive vias are produced for contact-making purposes. The front-side transmission element is formed in the metallization planes. All necessary connections to the outer side of the component are made by means of the conductive vias.

The rear side is then processed. During the rear-side processing, the substrate wafer is thinned to the desired thickness. Deep trenches are etched to have the rear side make contact with the front side via a metallization plane.

The coupling of the isolation element and thus also the isolation class or isolation voltage is dependent on the thickness of the substrate. Optionally, one or more etching stages can be provided to increase the coupling.

In a next step, the rear-side metallization is formed, in which at least one metallization plane is formed on the rear side of the semiconductor component. The rear-side transmission element is formed in this metallization plane.

Optionally, additional processing steps such as singulation, connection to other elements and/or encapsulation can be performed.

The semiconductor component according to the invention can be produced both by using and without using planarization methods. If a planarization method is not used, a topography is created.

The semiconductor component according to the invention or a preferred embodiment of the semiconductor component according to the invention are suitable in principle for use in products such as digital isolators, isolated gate drivers or isolated DC/DC converters. These products are required in the following technical fields of application:
Industrial automation and control: Use in sensors, control units and actuators for secure communication between different potentials and protection against transients and interference.
Medical technology: Ensure isolation in patient circuits in the case of appliances such as monitors, scanners, or defibrillators in order to ensure safety and protection.
Communication systems: Use in Ethernet or RS-485 networks for interference-free signal transmission and protection against voltage peaks in high-frequency environments.
Power and electricity supply systems: Isolation between control system and power electronics in applications such as inverters, uninterruptible power supplies (UPS), and smart grid technologies.
Automotive industry: Control and protection in high-voltage applications, for example battery management systems (BMS) or motor controllers in electric vehicles.
Test and measuring devices: Ensuring electrical isolation when measuring signals in high-voltage circuits and precision measuring devices.
Power converters and inverters: Control and isolation in solar energy systems, wind power plants and industrial drive systems.
Engine controllers: Actuation of AC, DC or BLDC motors in industrial plants or household appliances with optimization of switching times and minimization of losses.
Power converters: Application in switching converters (SMPS), DC/DC converters and bidirectional converters to ensure galvanic isolation between primary and secondary sides.
Power distribution and smart grid systems: Use in intelligent circuit breakers and transformers for safe control and isolation.
Charging systems for electric vehicles: Application in fast chargers and wireless charging systems for safe control of high-voltage components.
Photovoltaic systems: Use in inverters and data communication interfaces for isolating and safely controlling the modules.
Safety and protective measures: Isolation and protection against voltage flashovers, as well as the avoidance of fault currents that could be transmitted to control circuits.
Efficient switching control: Use in applications requiring fast switching times and low losses, especially in high-frequency and high-power applications.

### BRIEF DESCRIPTION OF THE DRAWINGS

Further preferred features of the invention are explained on the basis of exemplary embodiments and the figures. In this case, any dimensions given do not indicate any limitation beyond the claims. In the figures:

FIG. 1 shows a lateral cross section of one exemplary embodiment of a semiconductor component according to the invention;

FIG. 2A-2G show, using a series of figures, method steps of one exemplary embodiment of a production method according to the invention; and

FIG. 3 shows a top view of one exemplary embodiment of a semiconductor component according to the invention.

### DETAILED DESCRIPTION

Identical elements or elements having a identical effect are denoted by identical reference signs.

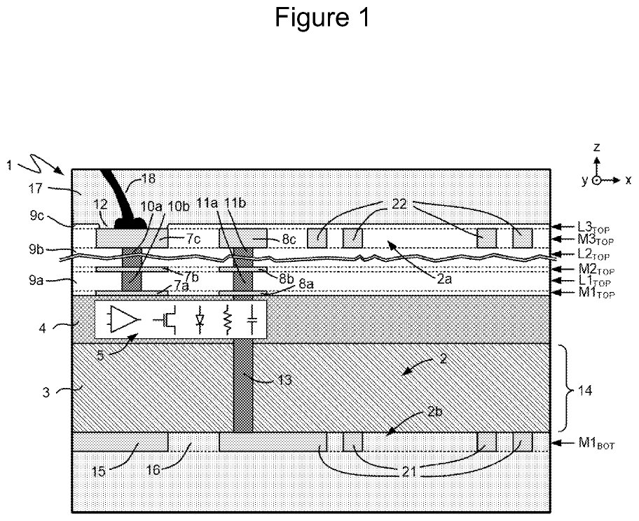

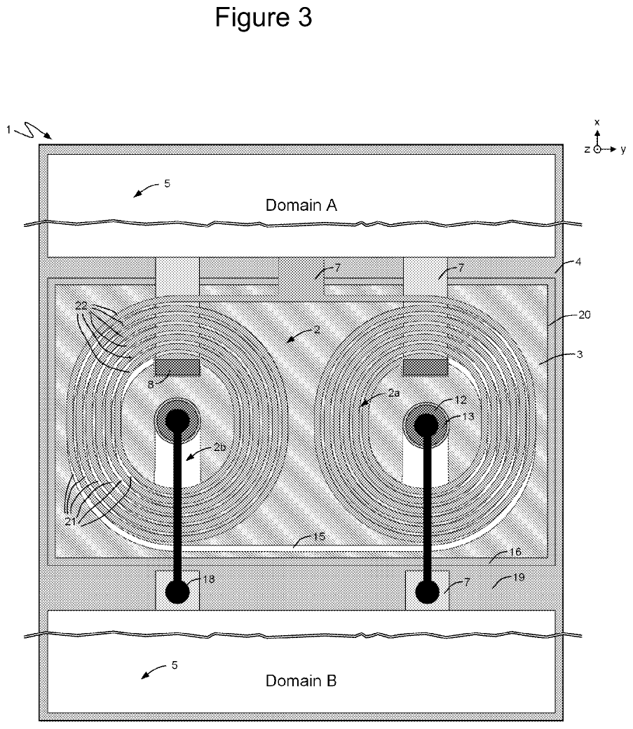

FIG. 1 shows the lateral cross section of one embodiment of a semiconductor component 1 according to the invention. In the present case, the semiconductor component 1 is formed having a microtransformer 2 with integrated circuits of a circuit domain A. FIG. 3 shows one exemplary embodiment containing circuits of the two circuit domains A and B.

In the present case, the isolating substrate 3 is in the form of a sapphire substrate and serves as a dielectric layer having a thickness 14 along the z-axis of 200 μmin the present case. The thickness 14 of the substrate is selected based on the voltage class required to ensure the desired galvanic isolation.

The isolating substrate 3 is used as a carrier substrate for the construction of the semiconductor layer structure 4, in this case based on AlGaN/GaN technology. A semiconductor layer structure 4 in the form of epitaxial layers for the corresponding semiconductor technology is grown on the substrate 3. For the AlGaN/GaN technology, an AlN nucleation layer, GaN buffer, GaN channel, AlGaN barrier and (p-)GaN cover are grown in this case. In addition, an etching step for the structuring of the p-GaN gate is carried out using AlGaN/GaN technology with normally-off (enhancement mode, e-mode), the formation of ohm contacts for making contact with the components and an implantation step for the isolation of the active components (in this case high-electron mobility transistors, HEMTs, Schottky barrier diodes, SBDs, lateral field-effect rectifiers, LFERs, etc.) or the passive components (2DEG resistor, p-GaN gate capacitor, or virtual metal layer realized by 2DEG layer). In this embodiment, various active components, such as normally-on and normally-off HEMTs, SBDs, LFERs, and passive components, such as resistors, capacitors and inductors, are available as AlGaN/GaN technology, using which the integrated circuits 5 of the circuit domain A and/or B can be realized. These components can be designed in principle as is known from the prior art.

The circuit domain A comprises active and passive circuit components, denoted by the reference sign 5, in the semiconductor layer structure 4. These active and passive circuit components are dependent on the desired functionality of the semiconductor component 1.

Furthermore, the circuit domain A for the transmission of data and/or power in this case comprises a transmitter or oscillator for DC/AC conversion, while circuit domain B contains the corresponding receiver or rectifier for AC/DC conversion. The integrated circuits operate at voltages>1 V.

In the present case, three metallization planes M1_{TOP}, M2_{TOP}, M3_{TOP}, each comprising corresponding metal area 7a, 7b, 7c, extend on the epitaxial layers of the semiconductor layer structure 4. The front-side transmission element 2a is formed in the third metallization plane M3_{TOP} in this case.

A rear-side metallization plane M1_{BOT} is formed on the bottom side of the substrate 3 facing away from the semiconductor layer structure. The rear-side transmission element 2b is formed in the rear-side metallization plane M1_{BOT} in this case.

The integrated microtransformer 2 thus comprises the front-side transmission element 2a, in this case in the form of an upper winding 21, here the primary winding, and the rear-side transmission element 2b, in this case in the form of a lower winding 22, here the secondary winding, of two spiral coils of an inductive coupling element for the galvanic isolation.

The metallization planes M1_{TOP}, M2_{TOP}, M3_{TOP} can also be used, for example, for gate contacts of the active components, field plates or connections between components as well as for the realization of passive structures, such as capacitances and inductors (not illustrated). In addition, the metallization planes M1_{TOP}, M2_{TOP}, M3_{TOP} may comprise additional metal areas 8a, 8b, 8c for vias to other planes of the semiconductor component 1.

The area between the front-side transmission element 2a and the rear-side transmission element 2b cannot be used for integrated circuits. This area with the corresponding dielectric layers also contributes to the isolation between the front-side transmission element 2a and the rear-side transmission element 2b.

Each metal layer on the top side M2_{TOP} and M3_{TOP} is connected to the underlying metal layer M1_{TOP} and M2_{TOP} by means of a via plane L1_{TOP} or L2_{TOP}, respectively, which comprise conductive vias 10a and 10b, and 11a and 11b. The vias 10a, 10b, 11a, 11b are made of metallic material in this case. Dielectric layers 9a-9c, for example made of silicon nitride or silicon oxide, are provided between respectively adjacent metallization planes of the metallization planes M1_{TOP}, M2 _{TOP}, M3_{TOP} and the next metallization plane M1_{TOP}, M2 _{TOP}, M3_{TOP} and along each metal area which is part of an identical metallization plane M1_{TOP}, M2 _{TOP}, M3_{TOP}.

For electrical connection to other circuit parts or the external environment of the semiconductor component 1, one or more electrical contact areas 7c made of metallic material are provided on the same metallization plane M3_{TOP} as the primary winding 2a. It is possible to make contact with the windings of the front-side transmission element 22 or other circuit parts via said electrical contact areas 7c. A bonding area 12 with bonding wire 18 is provided for the purpose of making contact. The bonding wire 18 and the bonding area 12 consist of conductive metallic material, in the present case gold or copper.

Only the bonding area 12 is exposed for contact-making purposes. All other structures are covered by a silicon nitride or silicon oxide layer 9c and are electrically isolated and protected. The topmost dielectric layer 9c is used simultaneously to passivate the outer side and to make available the bonding areas 12.

The cross section illustrated in FIG. 1 shows a technology using planarization methods. However, the semiconductor component 1 can be produced in principle without using planarization methods, which results in a topography.

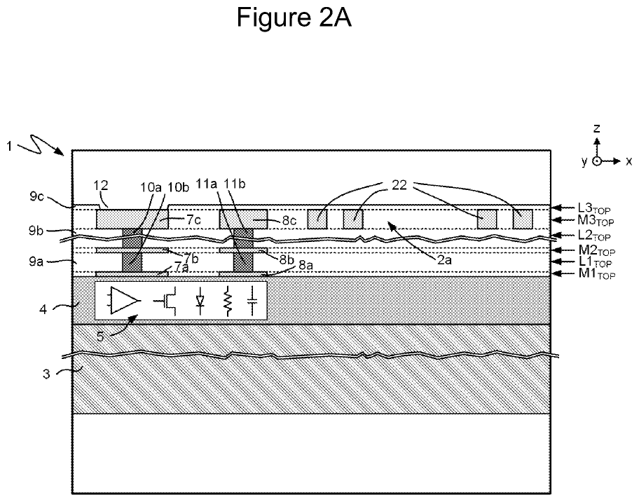

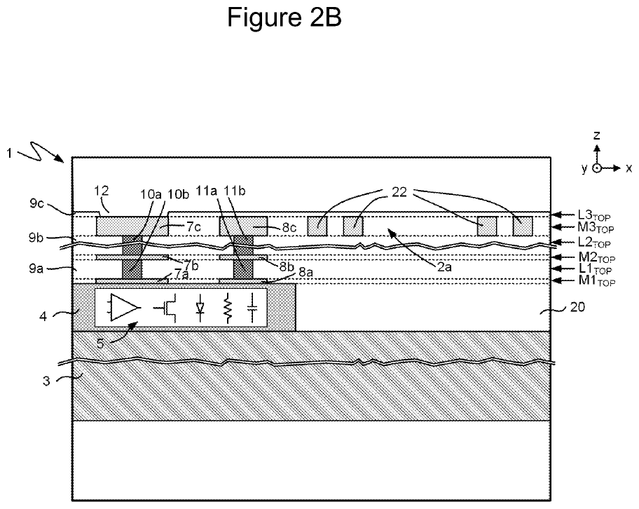

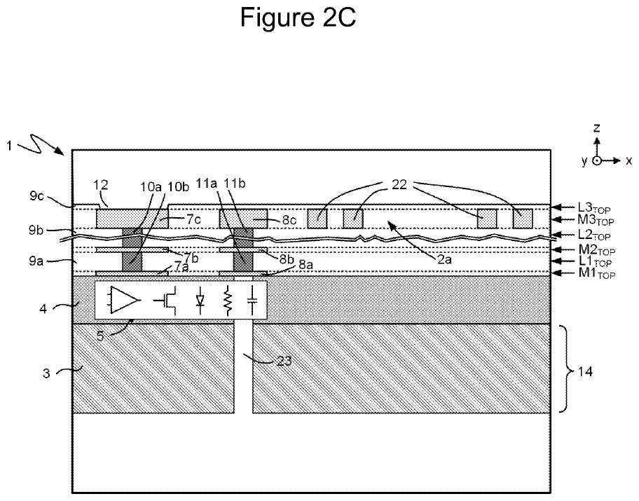

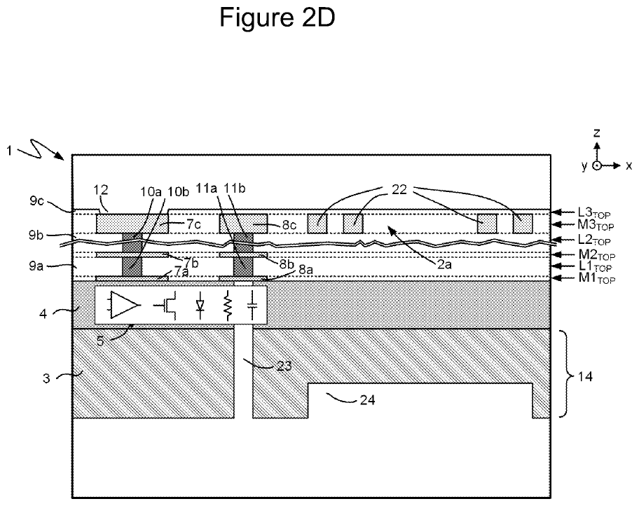

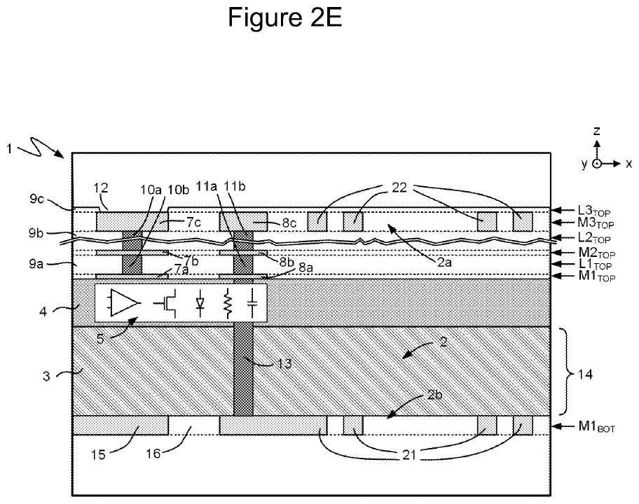

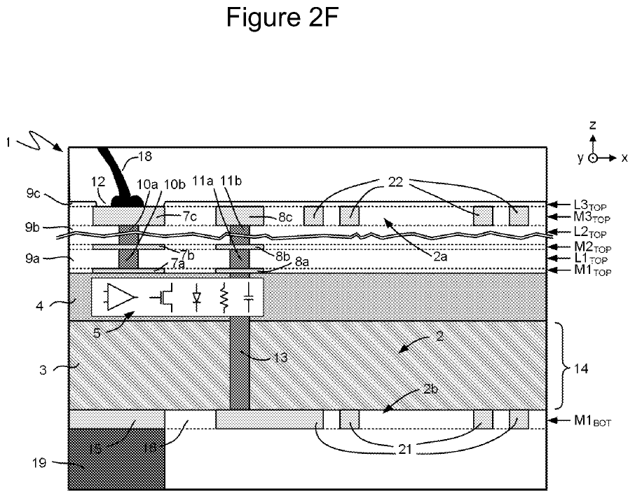

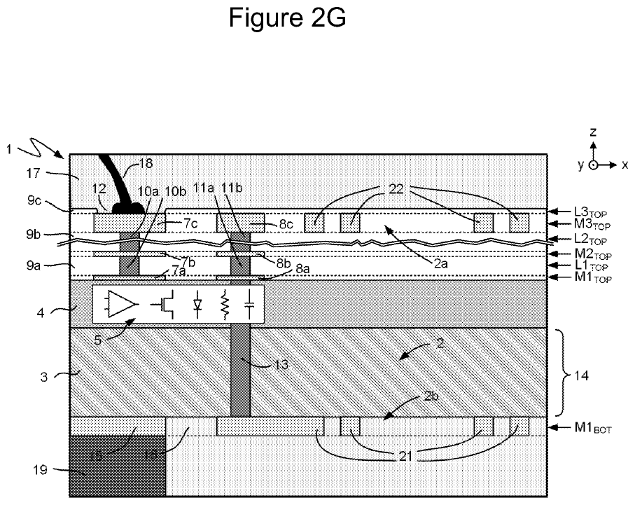

FIG. 2A-2G shows in cross section the method steps of one exemplary embodiment of a production method according to the invention.

FIG. 2A shows the cross section of the semiconductor component 1 after the front side has been processed. The semiconductor layer structure 4 is applied in the form of epitaxial layers to the substrate 3. The semiconductor layer structure 4 comprises multiple electrical active and passive circuit components 5 which have specific functions depending on the intended use of the semiconductor component. Regardless of the functions of the electronic circuits 5, their connections are electrically connected to the outer side of the semiconductor component 1 via the metal areas 7a-7c and the conductive connecting passages 10a-10b.

FIG. 2A in this case involves a semiconductor component formed using standard AlGaN/GaN technology. The substrate 3 is an isolating sapphire substrate in this case. The separation or isolation of the circuit components 5 can be established by means of implantation or etching.

FIG. 2B shows a variation of the front-side processing with an additional etching step or the combination with the isolation of the active components. For this purpose, the epitaxial layers of the semiconductor layer structure 4 are partially etched away 20 in the direction of the negative z-axis.

To ensure that the topography does not change, an additional planarization step can be carried out.

FIG. 2C shows the semiconductor component 1 after the first step of the rear-side processing. In this case, the substrate wafer 3 is thinned to a thickness 14 of 200 μm in this case. Subsequently, deep trenches are etched 23 so that the rear side makes contact with the front side via a metallization plane. The present case relates to a multi-stage etching process, in which a first selective etching stop is used on the GaN epitaxial layers of the semiconductor layer structure 4. The coupling of the isolation element, in the present case the microtransformer 2, is dependent on the vertical distance in the z direction. This results in the isolation class or maximum isolation voltage of the semiconductor component.

FIG. 2D shows a variant of the etching process from FIG. 2C with two etching steps: An etching stage 24 is formed in the substrate and the other etching stage is formed on the front side of the metallization plane M1_{TOP}, M2 _{TOP}, M3_{TOP}. The etching stages increase the coupling between the windings of the front-side transmission element 22 and the windings of the rear-side transmission element 21 and thus consequently the efficiency of the microtransformer.

FIG. 2E shows the cross section of the semiconductor component 1 after the rear-side metallization, in which an additional metallization plane M1_{BOT} is formed. The metallization 15 is structured accordingly with trenches 16 and can also be used for the via 13 to the front side of the semiconductor component. At the same time, the lower secondary winding 2b of the rear-side transmission element 21 with the individual windings is realized in this metallization plane M1_{BOT}.

After the rear side has been processed, the wafer can be laser-cut or sawn by means of standard singulation techniques and then picked so that it is only a single semiconductor component 1 that the integrated isolation element contains with possible active integrated circuit parts of the domain A and/or B. This semiconductor component 1 can be secured in a housing or on an additional carrier using typical securing techniques, such as soldering, adhesive bonding or sintering; see solder joint 19 in FIG. 2F. As an alternative, the semiconductor component 1 can also be embedded in a printed circuit board.

Wire bonding connections 18 are formed on the front side to be able to connect the semiconductor component to the external environment, as illustrated in FIG. 2F. This is done, for example, via pins in the case of a lead frame.

In a next step, the semiconductor component 1 is provided with an encapsulation, as shown in FIG. 2G. For this purpose, a lacquer or a resin layer 17 is applied, in the present case an epoxy resin, which covers the semiconductor component 1 both on the front side and on the rear side and forms a part of the packaging (not fully illustrated) of the semiconductor component 1. The resin layer 17 penetrates the trenches 16 and can further isolate the upper winding of the front-side transmission element 22 and the lower winding of the rear-side transmission element 21.

FIG. 3 shows an exemplary embodiment of a semiconductor component 1 according to the invention after singulation.

The semiconductor component 1 is formed with an inductive isolation element in the form of the front-side transmission element 22 and rear-side transmission element 21. The front-side transmission element 22 and the rear-side transmission element 21 are in the form of superimposed coils, each having two interconnected windings in the form of spiral coils.

The semiconductor component 1 has two integrated circuit domains A and B.

Both the circuit domain A and the circuit domain B comprise active and passive circuit components 5 in the epitaxial layers of the semiconductor layer structure 4 of the semiconductor component 1.

In this case, the circuit domain A comprises a transmitter or oscillator for DC/AC conversion (not illustrated), while circuit domain B contains the corresponding receiver or rectifier for AC/DC conversion (not illustrated). The integrated circuits operate at voltages>1 V.

The transmitter or oscillator is connected to the primary winding 2a of the front-side transmission element 22, while the receiver or rectifier is connected to the secondary winding 2b of the rear-side transmission element 21.

The front-side transmission element 22 is contacted via the contact areas 7. The rear-side transmission element 21 is also contacted via the front side of the semiconductor component by means of vias 13.

### List of reference signs

1 Semiconductor component
2 Microtransformer
2a Primary winding
2b Secondary winding
3 Substrate
4 Semiconductor layer structure
5 Active and passive circuit components
7a, 7b, 7c Metal areas/contact areas
8a, 8b, 8c Metal areas
9a, 9b, 9c Dielectric layer
10a, 10b Via
11a, 11b Via
12 Bonding area
13 Via
14 Thickness
15 Metallization
16 Structure/trenches
17 Lacquer/resin layer
18 Bonding wire
19 Solder joint
21 Rear-side transmission element
22 Front-side transmission element
23 Trenches
24 Substrate
L1_{TOP}, L2_{TOP} Via plane
M1, M2, M3 Metallization plane
M1_{TOP}, M2_{TOP}, M3_{TOP}Metallization plane on the top side
M1_{BOT} Metallization plane on the bottom side

1. A method for producing a semiconductor component with transmission of data and/or power between two galvanically isolated circuit domains, the method comprising the following steps:
A) providing an isolating substrate with a top side and a bottom side;
B) forming a semiconductor layer structure by growing and/or depositing epitaxial layers on the top side of the isolating substrate, by which circuits composed of active and/or passive circuit components of at least one of the two circuit domains are formed;
C) applying a front-side metallization in at least one front-side metallization plane indirectly or directly on the front side of the semiconductor layer structure facing away from the isolating substrate, wherein the front-side metallization comprises a front-side transmission element for galvanic isolation;
D) applying a rear-side metallization in at least one rear-side metallization plane indirectly or directly on the bottom side of the isolating substrate facing away from the semiconductor layer structure, wherein the rear-side metallization plane comprises a rear-side transmission element for galvanic isolation; and
E) forming an electrically conductive connection between the at least one of the two circuit domains from method step B and the front-side transmission element or the rear-side transmission element.

2. The method according to claim 1, wherein, in method step B, both of the galvanically isolated circuit domains are formed in the semiconductor layer structure in as a first circuit domain and a second circuit domain, and in an additional method step, an electrically conductive connection is formed between the first circuit domain and the front-side transmission element and between the second circuit domain and the rear-side transmission element, or in the additional method step, an electrically conductive connection is formed between the first circuit domain and the rear-side transmission element and between the second circuit domain and the front-side transmission element.

3. The method according to claim 1, wherein the semiconductor component is a monolithically integrated semiconductor component.

4. The method according to claim 1, wherein data and/or power is transmitted between the front-side transmission element and the rear-side transmission element inductively, capacitively and/or by f electromagnetic waves via an RF antenna arrangement.

5. The method according to claim 1, wherein the semiconductor layer structure is formed based on III-V compound semiconductors or silicon.

6. The method according to claim 1, wherein a thickness of the substrate is selected based on an isolation voltage of the semiconductor component required for the galvanic isolation.

7. The method according to claim 1, further comprising in a method step before method step E, etching an etching step at least in the substrate in an area between the front-side transmission element and the rear-side transmission element.

8. The method according to claim 1, further comprising removing the semiconductor layer structure from method step B in an area between the front-side transmission element and the rear-side transmission element in an additional method step, by etching.

9. A semiconductor component with data and/or power transmission between two galvanically isolated circuit domains, the semiconductor component comprising:
an isolating substrate;
a semiconductor layer structure comprising circuits composed of active and/or passive circuit components for at least a first circuit domain of the two galvanically isolated circuit domains;
at least one front-side metallization plane and at least one rear-side metallization plane;
wherein the semiconductor layer structure is arranged on a top side of the substrate and the front-side metallization plane is arranged indirectly or directly on the front side of the semiconductor layer structure facing away from the substrate, and has a front-side transmission element for galvanic isolation;
the rear-side metallization plane is arranged indirectly or directly on a bottom side of the substrate facing away from the semiconductor layer structure, and has a rear-side transmission element for galvanic isolation,
the front-side and the rear-side transmission elements are configured to interact to transmit data and/or power contactlessly via magnetic coupling, electrical coupling or electromagnetic waves between the front-side transmission element and the rear-side transmission element, and the first circuit domain is electrically conductively connected to the front-side transmission element or the rear-side transmission element.

10. The semiconductor component according to claim 9, wherein the semiconductor component is a monolithically integrated semiconductor component.

11. The semiconductor component according to claim 9, wherein the substrate has a thickness required for the galvanic isolation based on an isolation voltage of the semiconductor component.

12. The semiconductor component according to claim 9, wherein the semiconductor layer structure comprises a second circuit domain of the two galvanically isolated circuit domains and the first circuit domain is electrically conductively connected to the front-side transmission element and the second circuit domain is electrically conductively connected to the rear-side transmission element, or the first circuit domain is electrically conductively connected to the rear-side transmission element and the second circuit domain is electrically conductively connected to the front-side transmission element.

13. The semiconductor component according to claim 9, wherein the isolating substrate is arranged between the first and second transmission elements.

14. The semiconductor component according to claim 9, wherein the isolating substrate is made of sapphire, semi-isolating silicon carbide or comprises a silicon-on-isolator substrate.

15. The semiconductor component according to claim 9, wherein the front-side and the rear-side transmission elements for transmitting data and/or power comprise a coil pair, a capacitor or an RF antenna arrangement.

16. The semiconductor component according to claim 9, wherein the front-side and the rear-side transmission elements comprise coils, and a number of windings of the coils is between 1 and 30.

17. The semiconductor component according to claim 9, further comprising at least one first electrical contact area made of metallic material for making contact with one of the at least two circuit domains and a second electrical contact area made of metallic material for making contact with the rear-side transmission element are formed in the front-side metallization plane.

18. The semiconductor component according to claim 9, wherein the front-side metallization plane and/or the rear-side metallization plane are multi-layer, in that via planes are provided between metal layers of the front-side metallization plane, said via planes comprise conductive vias.

19. The semiconductor component according to claim 18, wherein at least one said via plane is provided in the front-side metallization plane, and said via plane has at least one conductive via through the isolating substrate to the rear-side metallization plane.

20. The semiconductor component according to claim 9, wherein the semiconductor layer structure is formed based on III-V compound semiconductors or silicon.
